(19) United States
(12) Patent Application Publication
(10) Pub. No.: US 2025/0311156 A1
(43) Pub. Date: Oct. 2, 2025

(54) Connector Shell Assembly and Connector

(71) Applicants: TE Connectivity India Private Limited, Bangalore (IN); Tyco Electronics (Shanghai) Co., Ltd., Shanghai (CN)

(72) Inventors: WenYu (Vindy) Liu, Shanghai (CN); Guangming (Suny) Zhao, Shanghai (CN); Remesh Kuzhikkali, Bangalore (IN); Yang (Eric) Shi, Shanghai (CN)

(73) Assignees: TE Connectivity India Private Limited, Bangalore (IN); Tyco Electronics (Shanghai) Co., Ltd., Shanghai (CN)

(21) Appl. No.: 19/091,255

(22) Filed: Mar. 26, 2025

(30) Foreign Application Priority Data
Mar. 28, 2024 (CN) 202410372465.3
Jun. 12, 2024 (CN) 202410758636.6

(51) Int. Cl. H05K 7/20; H01R 12/70; H01R 12/71; H01R 13/514; H01R 13/639

(52) U.S. Cl. CPC H05K 7/20272; H01R 12/7064; H01R 12/716; H01R 13/514; H01R 13/639; H05K 7/20418

(57) ABSTRACT

A connector shell assembly includes a shell, a plurality of bottom port heat sinks, and a bottom port liquid cooling plate. The shell has a row of bottom ports and a row of top ports adjacent to each other in a height direction. The shell also has a transverse slot between a top wall of the row of bottom ports and a bottom wall of the row of top ports. The plurality of bottom port heat sinks are each installed on the top wall of each bottom port. The bottom of each bottom port heat sink protrudes into one bottom port and thermally contacts a mating connector inserted into the one bottom port. The bottom port liquid cooling plate inserted into the transverse slot of the shell thermally contacts a top of each bottom port heat sink and cools the bottom port heat sink with a cooling liquid flowing therethrough.

### CROSS-REFERENCE TO RELATED APPLICATIONS

This application claims the benefit of the filing date under 35 U.S.C. § 119(a)-(d) of Chinese Patent Application No. CN202410372465.3 filed on Mar. 28, 2024, and Chinese Patent Application No. CN202410758636.6 filed on Jun. 12, 2024.

### FIELD OF THE INVENTION

The present invention relates to a connector shell assembly and, more particularly, to a connector comprising the connector shell assembly.

### BACKGROUND OF THE INVENTION

In the prior art, in order to improve the heat dissipation effect of connectors having multiple rows of ports, a heat sink is usually installed on the top wall of each port of the connector. The heat sink protrudes into the port to make thermal contact with the mating connector inserted into the port. However, in some applications, the specified heat dissipation effect cannot be achieved solely through the heat sink. Consequently, it is necessary to install a liquid cooling plate on the top wall of the top port of the connector, which is in thermal contact with the top of the heat sink on the top port to further improve the heat dissipation effect of the top port. However, in the prior art, there is no liquid cooling plate set up to dissipate heat from the bottom ports, which results in the heat dissipation performance of the bottom ports not meeting the predetermined requirements.

### SUMMARY OF THE INVENTION

A connector shell assembly includes a shell, a plurality of bottom port heat sinks, and a bottom port liquid cooling plate. The shell has a row of bottom ports and a row of top ports adjacent to each other in a height direction of the shell. The shell also has a transverse slot between a top wall of the row of bottom ports and a bottom wall of the row of top ports. The plurality of bottom port heat sinks are each installed on the top wall of each bottom port. The bottom of each bottom port heat sink protrudes into one bottom port and thermally contacts a mating connector inserted into the one bottom port. The bottom port liquid cooling plate inserted into the transverse slot of the shell thermally contacts a top of each bottom port heat sink and cools the bottom port heat sink with a cooling liquid flowing through the bottom port liquid cooling plate.

### BRIEF DESCRIPTION OF DRAWINGS

The invention will now be described by way of example with reference to the accompanying figures, of which:

FIG. 1 is a perspective view of a connector comprising a connector shell assembly having a bottom port liquid cooling plate inserted into a shell according to an exemplary embodiment;

FIG. 2 is a perspective view of the bottom port liquid cooling plate of FIG. 1 not inserted into the shell of FIG. 1;

FIG. 3 is a perspective view of a top of the bottom port liquid cooling plate of FIG. 1;

FIG. 4 is a perspective view of a bottom of the bottom port liquid cooling plate of FIG. 1;

FIG. 5 is a perspective view of the bottom port liquid cooling plate of FIG. 1 partially inserted into the shell of FIG. 1;

FIG. 6 is a perspective view of the bottom port liquid cooling plate of FIG. 1 in a pre-installation position and fully inserted into the shell of FIG. 1;

FIG. 7 is a perspective view of the bottom port liquid cooling plate of FIG. 1 moved to a final installation position;

FIG. 8 is a perspective view of a top of the shell of FIG. 1, with the bottom port liquid cooling plate of FIG. 1 in the final installation position;

FIG. 9 is a perspective view of the shell of FIG. 1 with a part of the shell removed, with the bottom port liquid cooling plate of FIG. 1 in the final installation position;

FIG. 10 is a transverse sectional view of the connector of FIG. 1, with the bottom port liquid cooling plate of FIG. 1 in the final installation position;

FIG. 11 is a partially enlarged sectional view of the connector of FIG. 1, with the bottom port liquid cooling plate of FIG. 1 in the final installation position;

FIG. 12 is a perspective view of a connector comprising a connector shell assembly having a bottom port liquid cooling plate inserted into a shell according to another exemplary embodiment;

FIG. 13 is a perspective view of the bottom port liquid cooling plate of FIG. 12 not inserted into the shell of FIG. 12;

FIG. 14 is a perspective view of the bottom port liquid cooling plate of FIG. 12;

FIG. 15 is a longitudinal sectional view of the connector of FIG. 12;

FIG. 16 is a perspective view of a connector comprising a connector shell assembly having a bottom port liquid cooling plate inserted into a shell according to another exemplary embodiment;

FIG. 17 is a perspective view of the bottom port liquid cooling plate of FIG. 16 not inserted into the shell of FIG. 16;

FIG. 18 is a longitudinal sectional view of the connector of FIG. 16;

FIG. 19 is a perspective view of a connector comprising a connector shell assembly according to another exemplary embodiment;

FIG. 20 is a longitudinal sectional view of the connector of FIG. 19;

FIG. 21 is a perspective view of a connector comprising a connector shell assembly having a bottom port liquid cooling plate inserted into a shell according to another exemplary embodiment;

FIG. 22 is a perspective view of the bottom port liquid cooling plate of FIG. 21 not inserted into the shell of FIG. 21;

FIG. 23 is a transverse sectional view of the connector of FIG. 21;

FIG. 24 is a perspective view of the connector of FIG. 21, in which an elastic locking piece for locking a bottom port liquid cooling plate is shown; and

FIG. 25 is an enlarged view of the elastic locking piece of FIG. 24.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

As used herein, an element recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

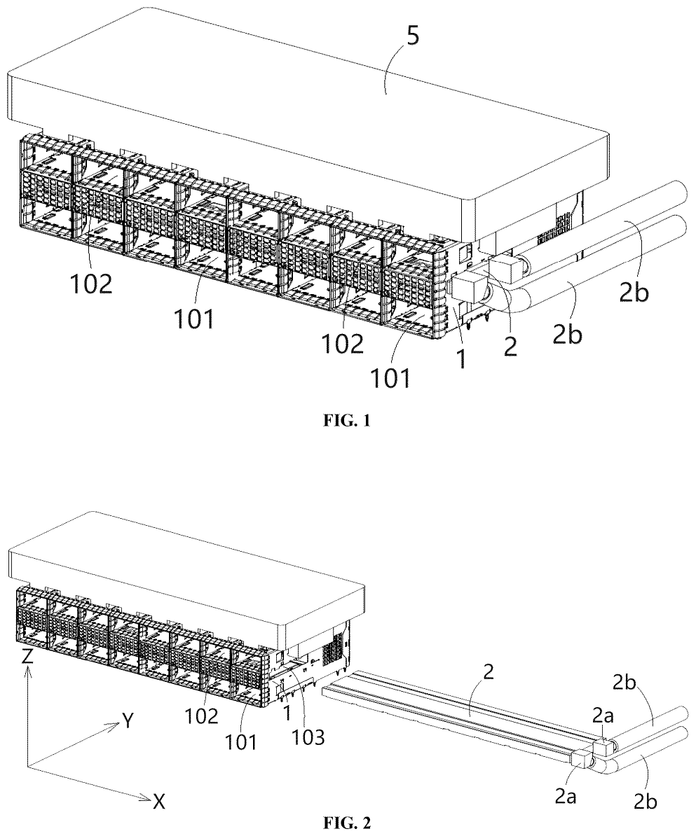

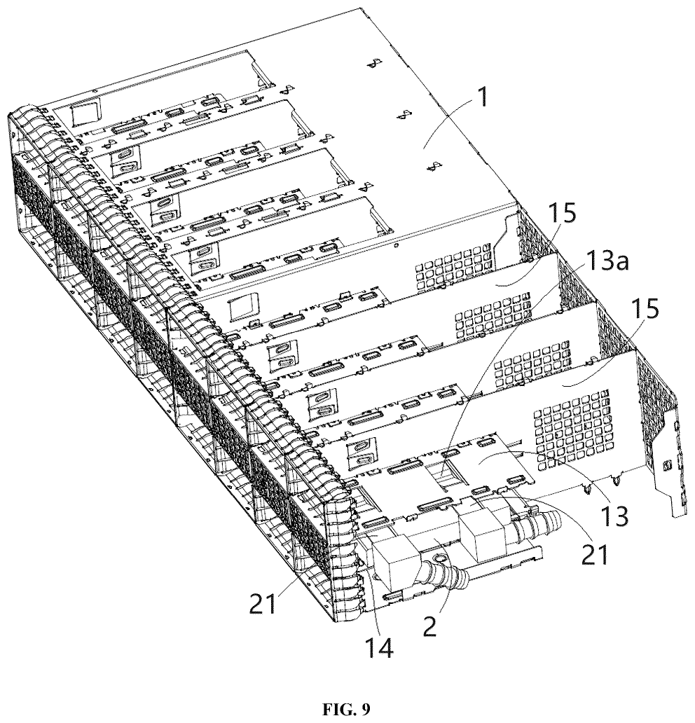

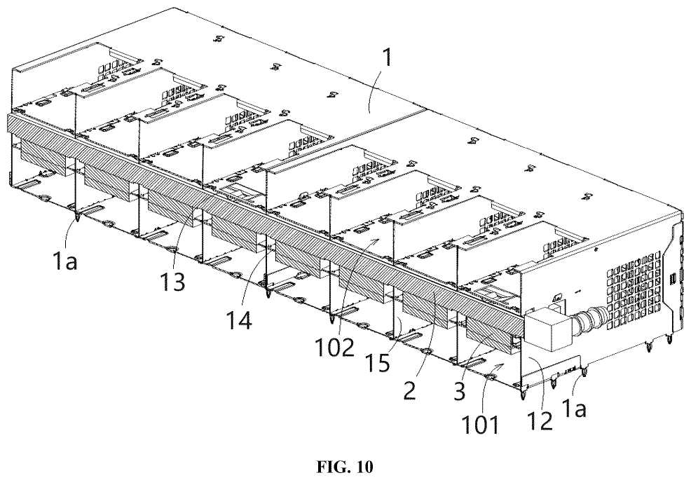

An exemplary embodiment of a connector shell assembly is now described with reference to FIGS. 1-11. As shown in FIGS. 10-11, the connector shell assembly comprises a shell 1, a row of bottom port heat sinks 3, and a bottom port liquid cooling plate 2. The shell 1, as shown in FIG. 10, has a row of bottom ports 101 and a row of top ports 102 adjacent to each other in a height direction Z of the shell 1. The shell 1 also has a transverse slot 103, as shown in FIG. 2, located between a top wall 14 of the row of bottom ports 101 and a bottom wall 13 of the row of top ports 102, as shown in FIG. 10. As shown in FIGS. 10-11, the row of bottom port heat sinks 3 are installed on the top wall 14 of the row of bottom ports 101. Bottoms of the row of bottom port heat sinks 3 protrude into the bottom ports 101, for thermal contact with mating connectors inserted into the bottom ports 101. As shown in FIGS. 2, 5-6, and 9-10, the bottom port liquid cooling plate 2 is inserted into the transverse slot 103 of the shell 1. As shown in FIGS. 9-10, the bottom port liquid cooling plate 2 is in thermal contact with the top of the row of bottom port heat sinks 3, to cool the row of bottom port heat sinks 3 with a cooling liquid flowing through the bottom port liquid cooling plate 2. In this way, the heat dissipation performance of the bottom ports 101 can be improved.

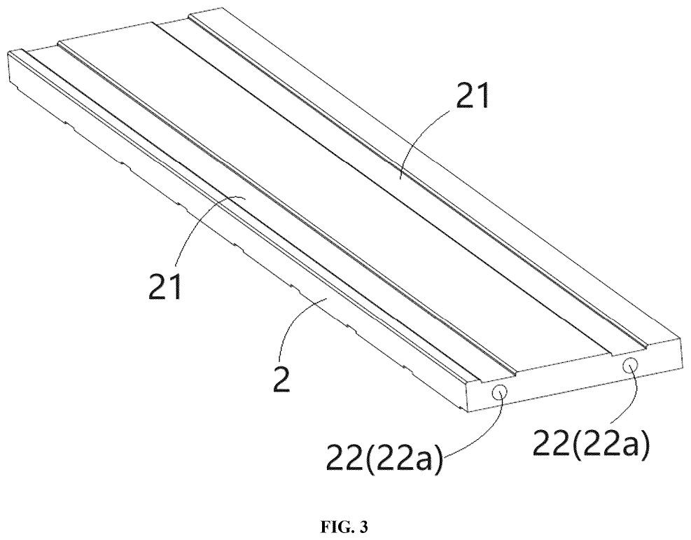

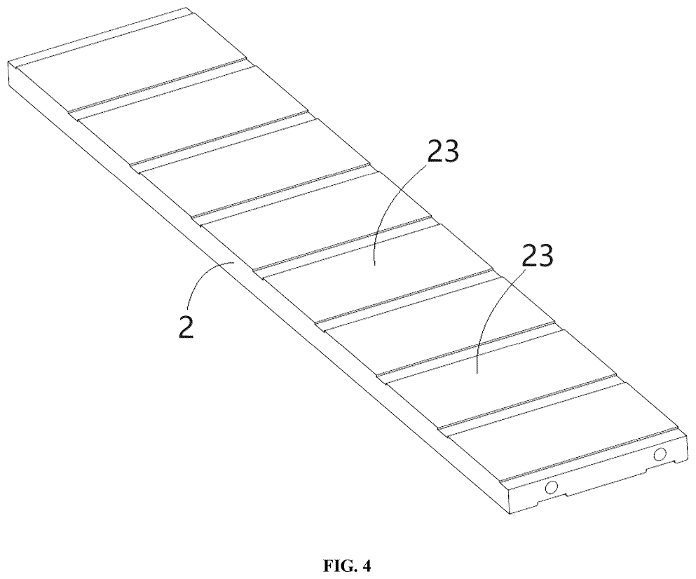

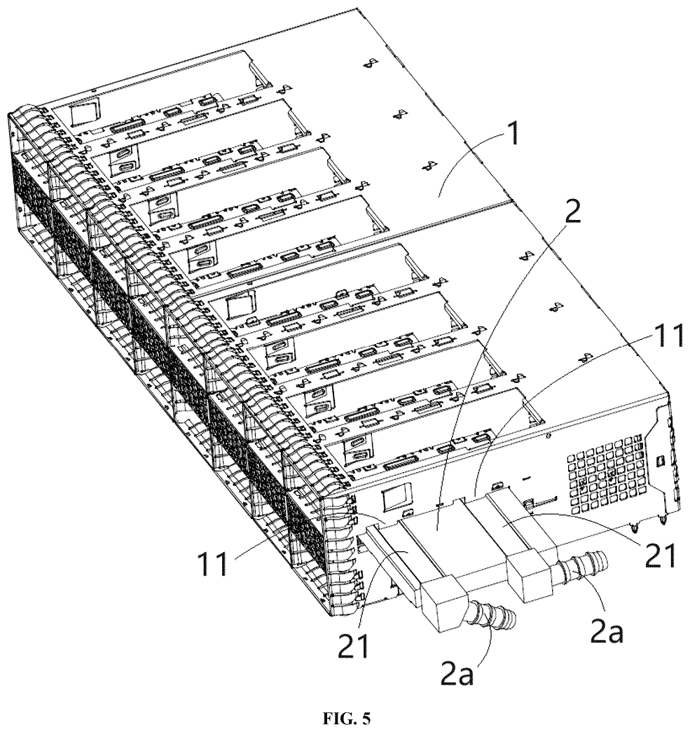

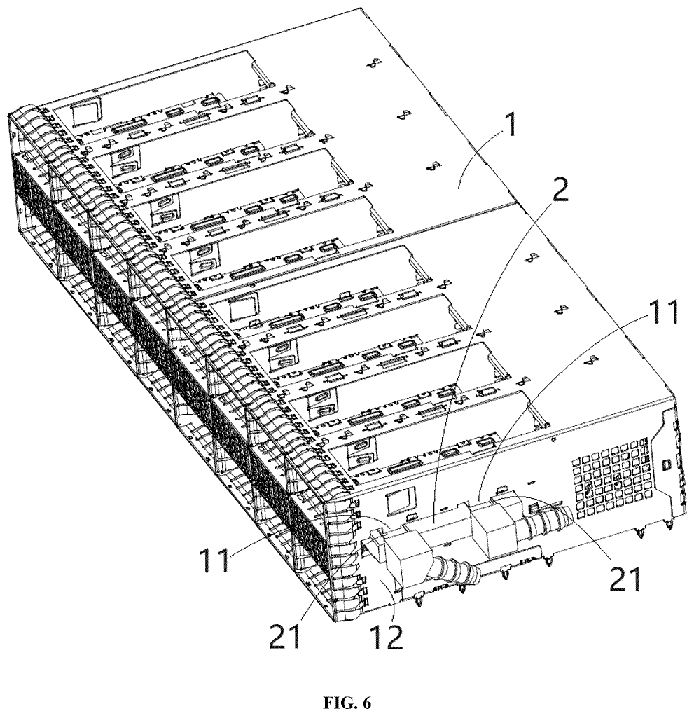

As shown in FIGS. 6-7 and 10, the shell 1 has two opposite side walls 12 in the transverse direction X of the shell 1. A protruding tongue 11, as shown in FIGS. 5-8, is formed on the side wall 12 of the shell 1, and a guide groove 21, as shown in FIG. 3, is formed on the top surface of the bottom port liquid cooling plate 2. The protruding tongue 11 is adapted to cooperate with the guide groove 21 to guide the bottom port liquid cooling plate 2 when inserted into the transverse slot 103 along the transverse direction X of the shell 1.

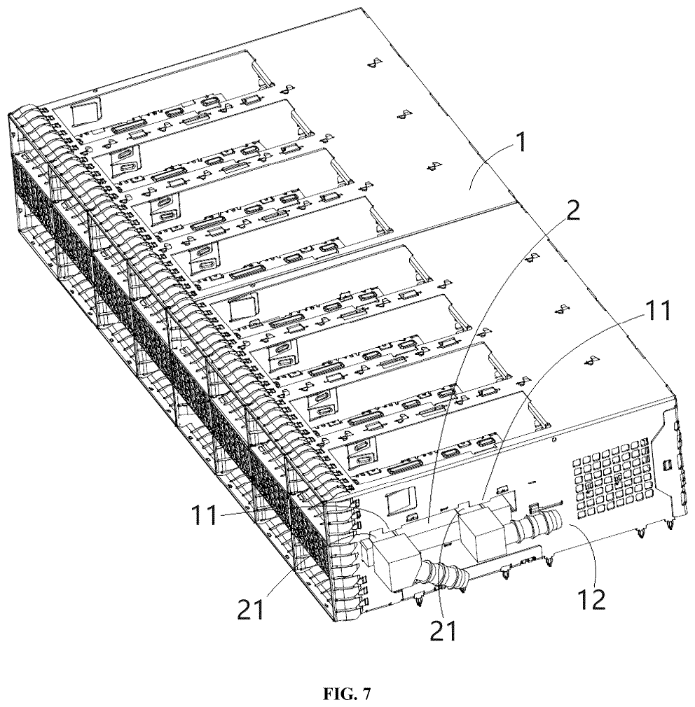

As shown in FIGS. 6-7, the bottom port liquid cooling plate 2 inserted into the transverse slot 103 can be moved relative to the shell 1 along a longitudinal direction Y of the shell 1 between the pre-installation position (the position shown in FIG. 6) and the final installation position (the position shown in FIG. 7). When the bottom port liquid cooling plate 2 is moved from the pre-installation position to the final installation position, the guide groove 21 disengages from the protruding tongue 11 and the protruding tongue 11 presses down on the top surface of the bottom port liquid cooling plate 2, ensuring reliable thermal contact between the bottom port liquid cooling plate 2 and the bottom port heat sink 3.

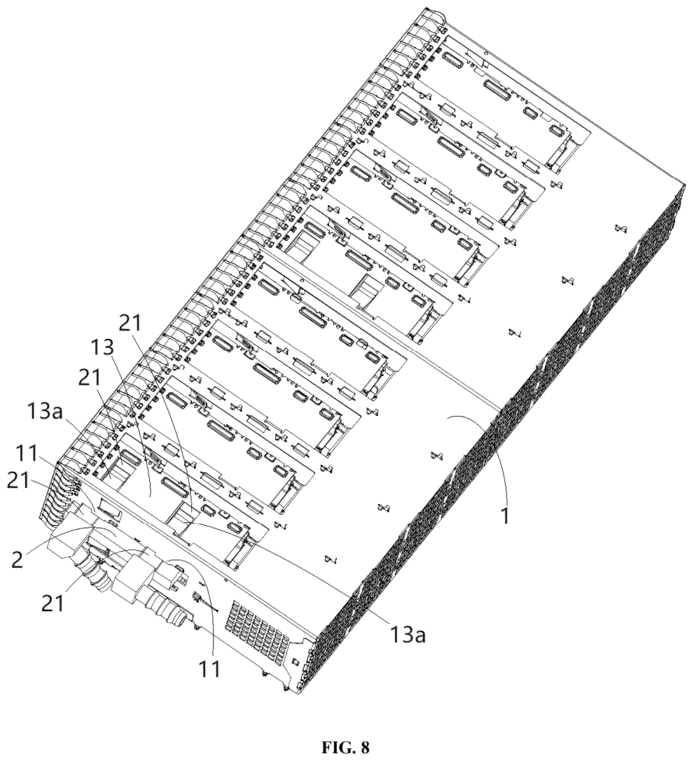

As shown in FIGS. 8-9 and 11, a locking spring 13a is formed on the bottom wall 13 of the top port 102. As shown in FIG. 6, when the bottom port liquid cooling plate 2 is in the pre-installation position, the locking spring 13a is in the unlocked position that is detached from the guide groove 21 on the bottom port liquid cooling plate 2. As shown in FIG. 7, when the bottom port liquid cooling plate 2 is moved to the final installation position, the locking spring 13a is in the locking position engaged with the guide groove 21 on the bottom port liquid cooling plate 2 to lock the bottom port liquid cooling plate 2 in the final installation position.

As shown in FIGS. 9-11, the shell 1 has at least one partition wall 15 located between its two side walls 12. The shell 1 also has a row of limiting protrusions 23, as shown in FIGS. 4 and 11, corresponding to the row of bottom ports 101 formed on the bottom surface of the bottom port liquid cooling plate 2. When the bottom port liquid cooling plate 2 is in the pre-installation position, the limiting protrusion 23 is in a position that does not interfere with the side wall 12 and partition wall 15 of the shell 1, thereby allowing the bottom port liquid cooling plate 2 to move along the transverse direction X of the shell 1. When the bottom port liquid cooling plate 2 is in the final installation position, the limiting protrusion 23 is in a position that interferes with the side wall 12 and partition wall 15 of the shell 1 to prevent the bottom port liquid cooling plate 2 from being moved along the transverse direction X of the shell 1.

As shown in FIGS. 3-4, the bottom port liquid cooling plate 2 is a single rectangular plate with a predetermined thickness. The bottom port liquid cooling plate 2 has two opposite ends in its length direction (i.e., the transverse direction X of the shell 1) and two opposite sides in its width direction (i.e., the longitudinal direction Y of the shell 1). As shown in FIG. 3, a liquid cooling channel 22 is formed in the bottom port liquid cooling plate 2 to allow the flow of cooling liquid, and two openings 22a are formed on the end face of one end of the bottom port liquid cooling plate 2 to communicate with the liquid cooling channel 22. The two openings 22a are respectively close to both sides of the bottom port liquid cooling plate 2, with one opening serving as the cooling liquid inlet and the other as the cooling liquid outlet.

As shown in FIGS. 1-2, the connector shell assembly further includes two connection pipes 2b, which are respectively connected to two openings 22a on the bottom port liquid cooling plate 2, for connecting the bottom port liquid cooling plate 2 to a cooling circuit. One of the two connection pipes 2b is used as an inlet pipe, and the other is used as an outlet pipe.

As shown in FIGS. 2 and 5, the connector shell assembly further includes two pipe joints 2a, which are respectively connected to the two openings 22a of the bottom port liquid cooling plate 2. As shown in FIG. 2, two connection pipes 2b are respectively connected to the two openings 22a of the bottom port liquid cooling plate 2 through two pipe joints 2a.

The connector shell assembly further includes a top port liquid cooling plate 5, as shown in FIG. 1, and a row of top port heat sinks. The row of top port heat sinks are installed on the top wall of a row of top ports 102, with the bottoms of the row of top port heat sinks protruding into the top ports 102, for thermal contact with the mating connectors inserted into the top ports 102. The top port liquid cooling plate 5 is installed on the top of the shell 1 and the top port heat sinks, and is in thermal contact with the top of the top port heat sinks. A liquid cooling channel is formed in the top port liquid cooling plate 5 to allow the flow of cooling liquid. The liquid cooling channel has inlet and outlet ports for connecting with the inlet and outlet pipes, respectively.

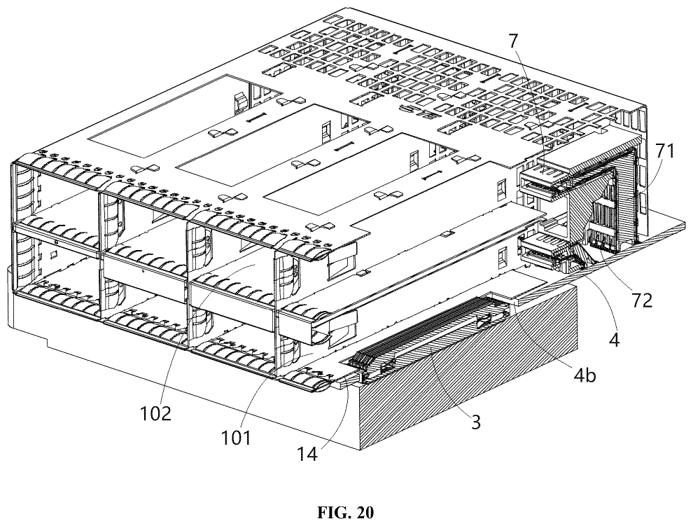

An exemplary embodiment of a connector is now described with reference to FIGS. 1-11. The connector includes the connector shell assembly according to FIGS. 1-11, and two rows of terminal modules 7 (e.g., like the terminal modules 7 shown in FIG. 20). Two rows of terminal modules 7 are installed into the shell 1 and correspond to a row of bottom ports 101 and a row of top ports 102, respectively. Each terminal module 7 has an insulator 71 and terminals 72 arranged within the insulator 71 (see FIG. 20). The terminals 72 mate with the mating terminal of the inserted mating connector.

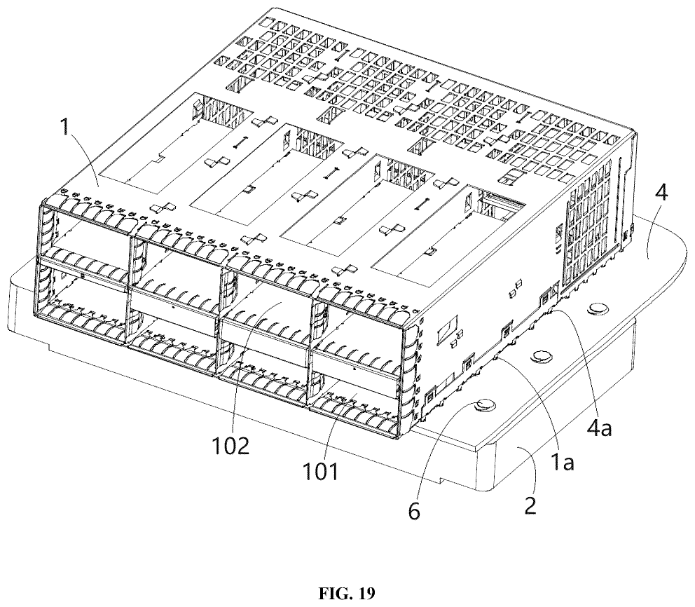

The connector further comprises a circuit board 4 (e.g., like the circuit board 4 shown in FIGS. 19 and 20). The bottom of the shell 1 is fixed to the circuit board 4, and the terminal 72 is electrically connected to the circuit board 4.

As shown in FIG. 10, a pin 1a is formed at the bottom of the shell 1, and a hole 4a is formed in the circuit board 4 (see FIG. 19). The pin 1a is press fit into the hole 4a to fix the shell 1 to the circuit board 4.

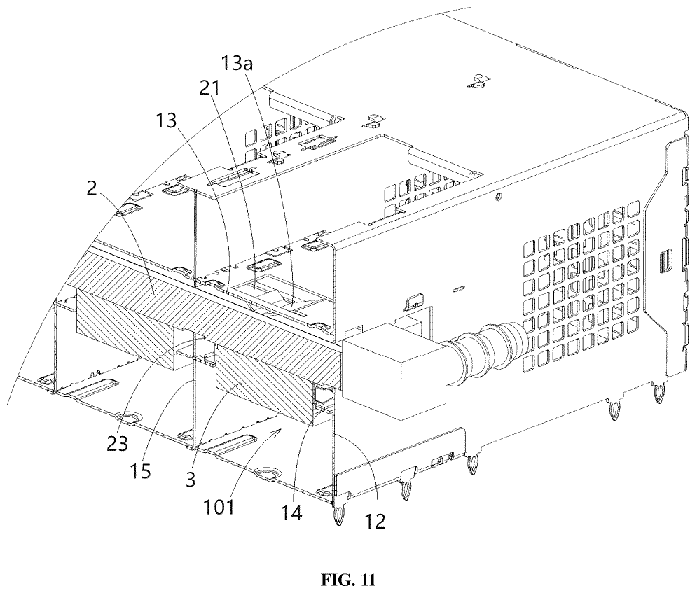

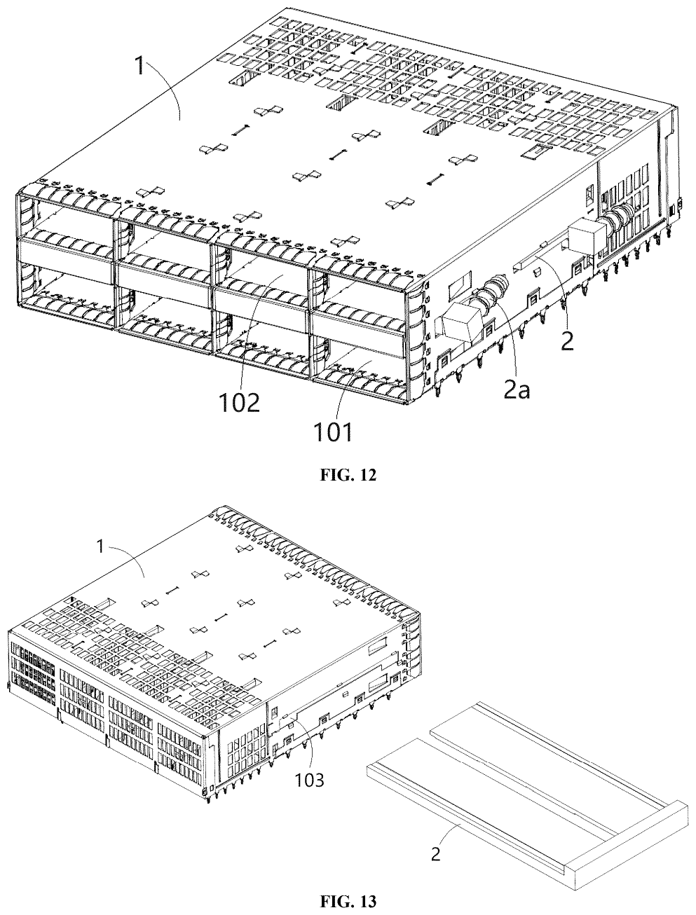

Another exemplary embodiment of a connector shell assembly is now described with reference to FIGS. 12-15. The main difference between the embodiment shown in FIGS. 12-15 and the embodiment shown in FIGS. 1-11 is the size and structure of the bottom port liquid cooling plate 2 and the transverse slot 103.

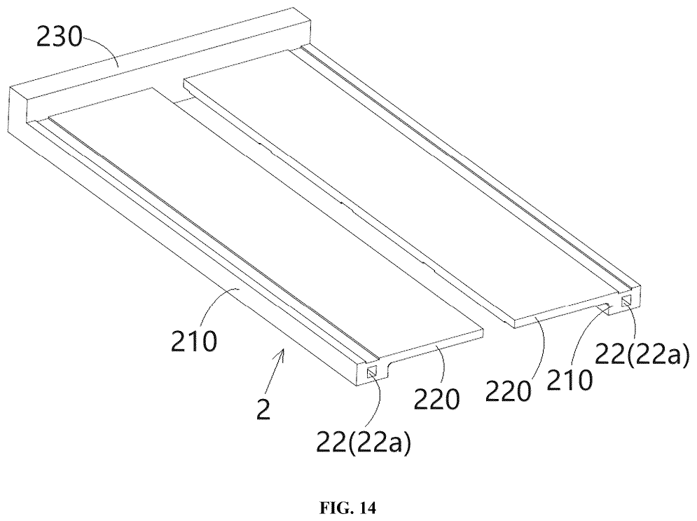

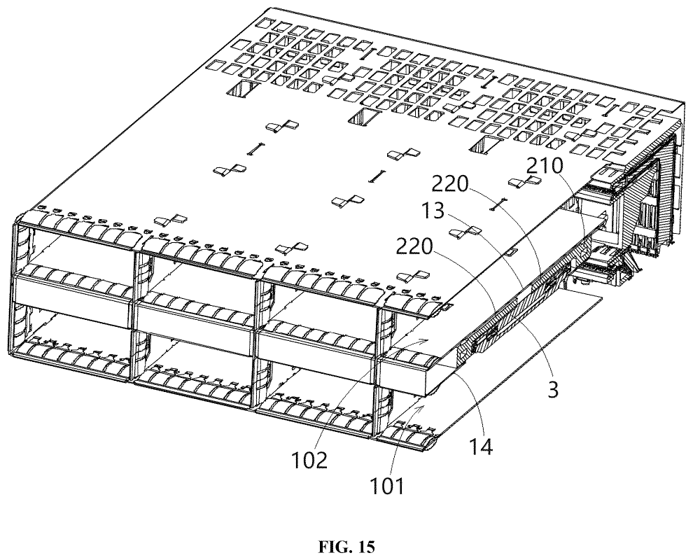

As shown in FIG. 14, the bottom port liquid cooling plate 2 includes a pair of strip-shaped bodies 210, a pair of thin plate parts 220, and an end body 230. The pair of strip-shaped bodies 210 are opposite in the width direction of the bottom port liquid cooling plate 2 (i.e., the longitudinal direction Y of the shell 1) and extend along the length direction of the bottom port liquid cooling plate 2 (i.e., the transverse direction X of the shell 1). The pair of thin plate parts 220 are located between the pair of strip-shaped bodies 210 and are respectively connected to the pair of strip-shaped bodies 210. The end body 230 extends along the width direction of the bottom port liquid cooling plate 2 and is connected to one end of the pair of strip-shaped bodies 210 and the pair of thin plate parts 220. A thickness of the pair of strip-shaped bodies 210 and the end body 230 is greater than a thickness of the pair of thin plate parts 220. The pair of thin plate parts 220 are spaced opposite each other in the width direction of the bottom port liquid cooling plate 2, and are used for thermal contact with the top of a row of bottom port heat sinks 3, as shown in FIG. 15.

As shown in FIG. 14, a liquid cooling channel 22 is formed in the pair of strip-shaped bodies 210 and the end body 230 to allow the flow of cooling liquid. Two openings 22a are formed on the end faces of the other ends of the pair of strip-shaped bodies 210, which are connected to the liquid cooling channel 22. One of the two openings 22a is used as a cooling liquid inlet, and the other is used as a cooling liquid outlet.

Except for the differences described above, the technical features of the embodiment shown in FIGS. 12-15 are essentially the same as those of the embodiment shown in FIGS. 1-11.

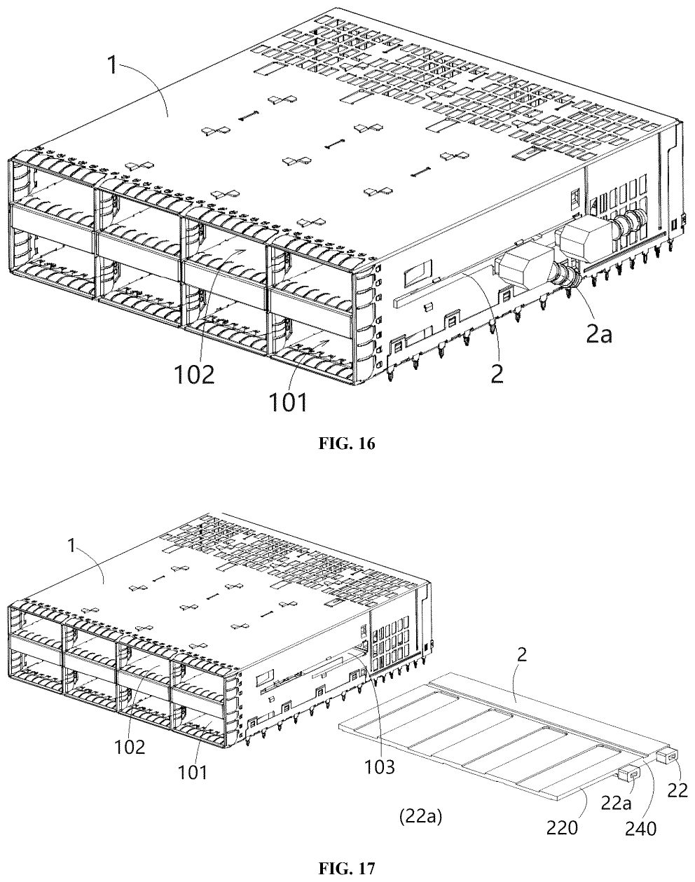

Another exemplary embodiment of a connector shell assembly is now described with reference to FIGS. 16-18. The main difference between the embodiment shown in FIGS. 16-18 and the embodiment shown in FIGS. 1-11 is the size and structure of the bottom port liquid cooling plate 2 and the transverse slot 103.

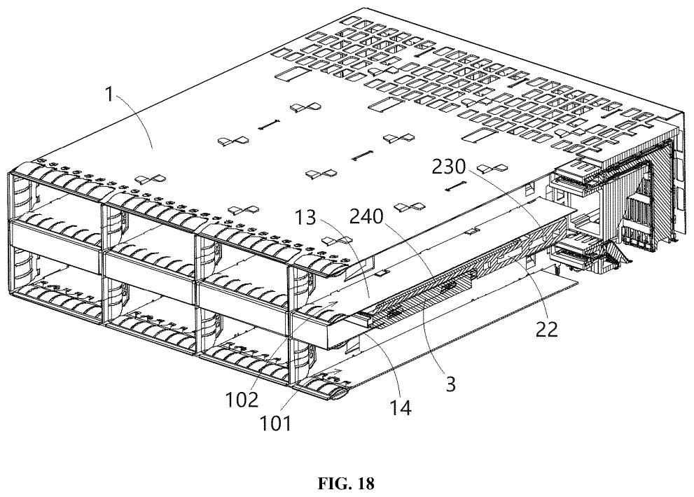

As shown in FIG. 17, the bottom port liquid cooling plate 2 includes a thick plate part 240 and a thin plate part 220. As shown in FIG. 18, the thick plate part 240 extends along the length direction (i.e., the transverse direction X of the shell 1) of the bottom port liquid cooling plate 2 at one side in the width direction (i.e., the longitudinal direction Y of the shell 1) of the bottom port liquid cooling plate 2. The thin plate part 220, as shown in FIG. 17, extends along the length direction of the bottom port liquid cooling plate 2 at the other side in the width direction of the bottom port liquid cooling plate 2. The thickness of the thick plate part 240 is greater than that of the thin plate part 220, and one side of the thin plate part 220 is connected to one side of the thick plate part 240. The thin plate part 220 is used for thermal contact with the top of a row of bottom port heat sinks 3.

As shown in FIG. 17, a liquid cooling channel 22 is formed in the thick plate part 240 to allow the flow of cooling liquid. Two openings 22a are formed on the end faces of one end of the thick plate part 240, which are connected to the liquid cooling channel 22. One of the two openings 22a is used as a cooling liquid inlet, and the other is used as a cooling liquid outlet.

Except for the differences described above, the technical features of the embodiment shown in FIGS. 16-18 are essentially the same as those of the embodiment shown in FIGS. 1-11.

Another exemplary embodiment of a connector shell assembly is now described with reference to FIGS. 19-20. As shown in FIGS. 19-20, the connector shell assembly comprises a shell 1, a row of bottom port heat sinks 3, a circuit board 4, and a bottom port liquid cooling plate 2. The shell 1 has a row of bottom ports 101 and a row of top ports 102 adjacent to each other in a height direction Z of the shell 1. The row of bottom port heat sinks 3, as shown in FIG. 20, are installed on the bottom wall 13 (see the previous embodiments respectively shown in FIGS. 1-18) of the row of bottom ports 101, with their tops protruding into the bottom ports 101, for thermal contact with mating connectors inserted into the bottom ports 101. As shown in FIG. 20, the circuit board 4 is formed with a row of cutouts 4b that allow the bottom of the row of bottom port heat sinks 3 to pass through, and the shell 1 is fixed to the top surface of the circuit board 4. The bottom port liquid cooling plate 2 is fixed to the bottom surface of the circuit board 4 and is in thermal contact with the bottom of the row of bottom port heat sinks 3. A liquid cooling channel 22 (see the previous embodiments respectively shown in FIGS. 1-18) is formed in the bottom port liquid cooling plate 2 to allow the flow of cooling liquid. The liquid cooling channel 22 has inlet and outlet ports for connecting to the inlet and outlet pipes, respectively.

As shown in FIG. 19, the bottom port liquid cooling plate 2 can be detachably fastened to the bottom surface of the circuit board 4 through threaded connection members 6. In this way, rapid replacement of the bottom port liquid cooling plate 2 can be achieved.

The connector shell assembly further includes a row of top port heat sinks and a top port liquid cooling plate 5 (like that of the top port liquid cooling plate 5 shown in reference to the embodiment shown in FIGS. 1-11). The row of top port heat sinks are installed on the top wall of the row of top ports 102, with the bottom of the row of top port heat sinks protruding into the top ports 102, for thermal contact with the mating connectors inserted into the top ports 102. The top port liquid cooling plate 5 is installed on the top of the shell 1 and the top port heat sinks. The top port liquid cooling plate 5 is in thermal contact with the top of the top port heat sinks. A liquid cooling channel is formed in the top port liquid cooling plate 5 to allow the flow of cooling liquid. The liquid cooling channel has inlet and outlet ports for connecting with the inlet and outlet pipes, respectively.

Another exemplary embodiment of a connector is now described with reference to FIGS. 19-20. The connector includes the connector shell assembly according to FIGS. 19-20 and two rows of terminal modules 7, as shown in FIG. 20. Two rows of terminal modules 7 are installed into the shell 1 and correspond to the row of bottom ports 101 and the row of top ports 102, respectively. As shown in FIG. 20, each terminal module 7 has an insulator 71 and terminals 72 arranged within the insulator 71. One end of terminal 72 is used to mate with the mating terminal of the inserted mating connector, and the other end of terminal 72 is electrically connected to the circuit board 4.

A pin 1a (see FIG. 10) is formed at the bottom of the shell 1, and a hole 4a, shown in FIG. 19, is formed in the circuit board 4. As shown in FIG. 19, the pin 1a is press fit into the hole 4a to fix the shell 1 to the circuit board 4.

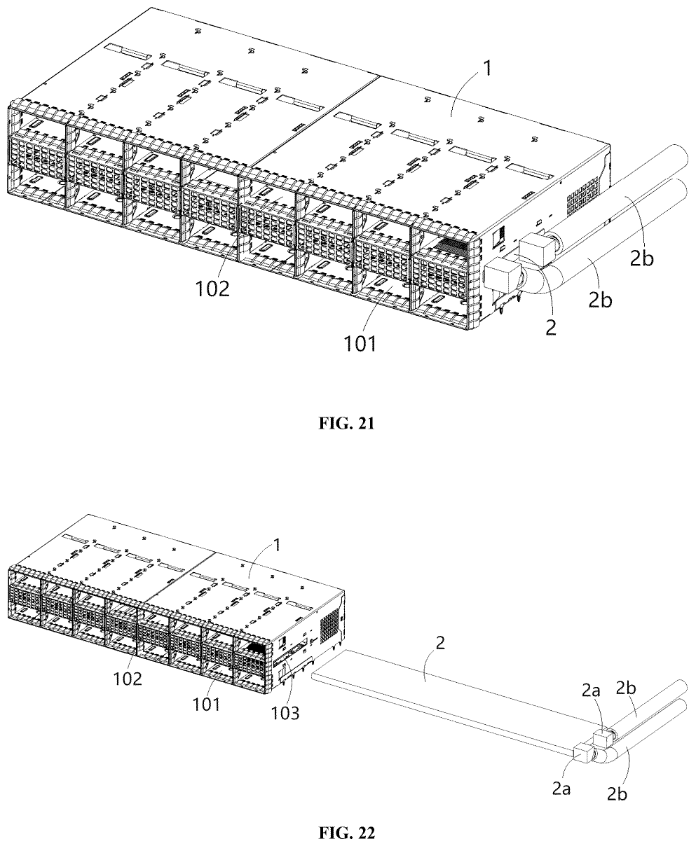

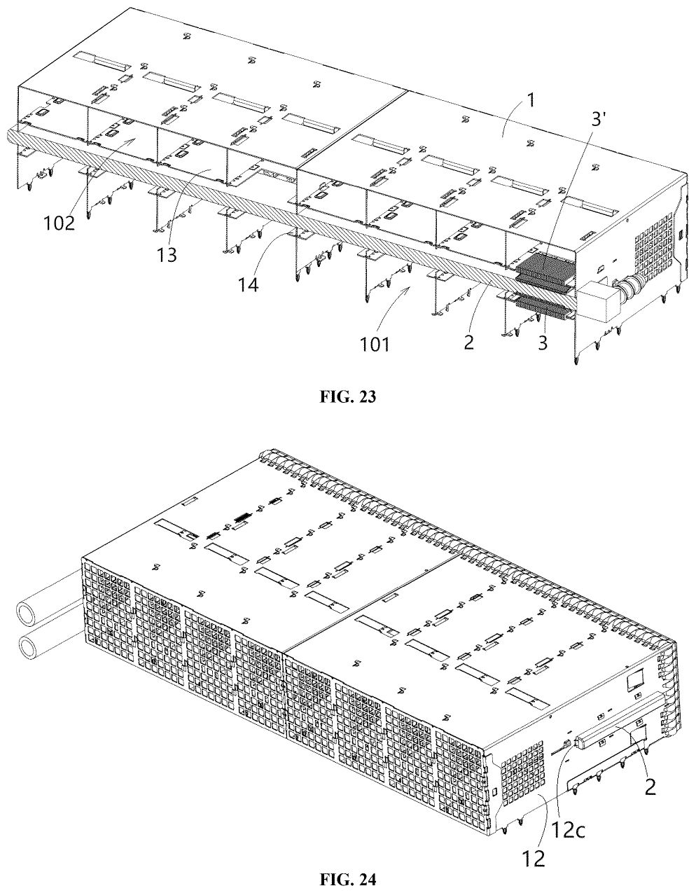

Another exemplary embodiment of a connector shell assembly is now described with reference to FIGS. 21-25. As shown in FIG. 23, the connector shell assembly comprises a shell 1, a bottom port heat sink 3, a top port heat sink 3′, and a bottom port liquid cooling plate 2. As shown in FIGS. 21-23, the shell 1 has a bottom port 101 and a top port 102 adjacent to each other in a height direction Z of the shell 1, as well as a transverse slot 103 located between the top wall 14 of bottom port 101 and the bottom wall 13 of top port 102. The bottom port heat sink 3, as shown in FIG. 23, is installed on the top wall 14 of the bottom port 101 and its bottom protrudes into the bottom port 101 for thermal contact with the mating connector inserted into the bottom port 101. As shown in FIG. 23, the top port heat sink 3′ is installed on the bottom wall 13 of the top port 102 and its bottom protrudes into the top port 102 for thermal contact with the mating connector inserted into the top port 102. The bottom port liquid cooling plate 2 is inserted into the transverse slot 103 of the shell 1 and is in thermal contact with both the bottom port heat sink 3 and the top port heat sink 3′, as shown in FIG. 23, in order to cool the bottom port heat sink 3 and the top port heat sink 3′ through the cooling liquid flowing through the bottom port liquid cooling plate 2.

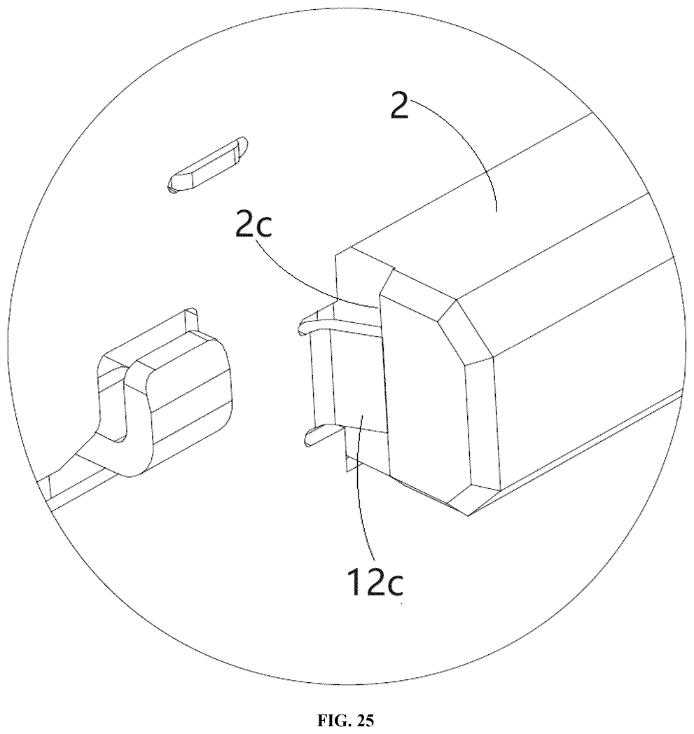

As shown in FIG. 24, the shell 1 has two opposite side walls 12 in a transverse direction X of the shell 1. The transverse slot 103, as shown in FIG. 22, has an inlet located on one side wall 12 of the shell 1 and an outlet located on the other side wall 12 of the shell 1. The bottom port liquid cooling plate 2 is inserted from the inlet of the transverse slot 103 and one end of which extends from the outlet of the transverse slot 103. As shown in FIGS. 24-25, an elastic locking piece 12c is formed on the other side wall 12 of the shell 1, and a locking step 2c is formed on one end of the bottom port liquid cooling plate 2. The elastic locking piece 12c rests against the locking step 2c to lock the bottom port liquid cooling plate 2 in the transverse slot 103.

A liquid cooling channel (similar to those shown in the other embodiments respectively shown in FIGS. 1-18) is formed in the bottom port liquid cooling plate 2 to allow the flow of cooling liquid, and two openings are formed on the end face of the other end of the bottom port liquid cooling plate 2 to communicate with the liquid cooling channel. The connector shell assembly also includes two pipe joints 2a, as shown in FIG. 22, connected to the two openings of the liquid cooling channel, and two connection pipes 2b, as shown in FIGS. 21-22, connected to the two pipe joints 2a. One of the two connection pipes 2b is used as an inlet pipe, and the other is used as an outlet pipe.

In the aforementioned exemplary embodiments according to the present invention, the various bottom port liquid cooling plates 2 can greatly improve the heat dissipation performance of the bottom ports 101, so that the heat dissipation performance of the bottom ports 101 can meet specified requirements.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

1. A connector shell assembly, comprising:
a shell having a row of bottom ports and a row of top ports adjacent to each other in a height direction of the shell, and a transverse slot between a top wall of the row of bottom ports and a bottom wall of the row of top ports;
a plurality of bottom port heat sinks each installed on the top wall of each bottom port, a bottom of each bottom port heat sink protrudes into one bottom port and thermally contacts a mating connector inserted into the one bottom port; and
a bottom port liquid cooling plate inserted into the transverse slot of the shell thermally contacts a top of each bottom port heat sink and cools the bottom port heat sink with a cooling liquid flowing through the bottom port liquid cooling plate.

2. The connector shell assembly of claim 1, wherein the shell has two side walls opposite each other in a transverse direction of the shell, and a protruding tongue formed on one side wall of the two side walls, a guide groove is formed on a top surface of the bottom port liquid cooling plate, the protruding tongue and the guide groove guide the bottom port liquid cooling plate into the transverse slot along the transverse direction.

3. The connector shell assembly of claim 2, wherein the bottom port liquid cooling plate inserted into the transverse slot is movable relative to the shell along a longitudinal direction of the shell between a pre-installation position and a final installation position, when the bottom port liquid cooling plate is moved from the pre-installation position to the final installation position the guide groove disengages from the protruding tongue and the protruding tongue presses down on the top surface of the bottom port liquid cooling plate, ensuring reliable thermal contact between the bottom port liquid cooling plate and the bottom port heat sink.

4. The connector shell assembly of claim 3, wherein a locking spring is formed on the bottom wall of the row of top ports, when the bottom port liquid cooling plate is in the pre-installation position the locking spring is in an unlocked position where it is detached from the guide groove, when the bottom port liquid cooling plate is moved to the final installation position the locking spring is in a locking position that engages with the guide groove to lock the bottom port liquid cooling plate in the final installation position.

5. The connector shell assembly of claim 3, wherein the shell has at least one partition wall located between the two side walls, a limiting protrusion corresponding to the row of bottom ports is formed on a bottom surface of the bottom port liquid cooling plate, when the bottom port liquid cooling plate is in the pre-installation position the limiting protrusion is in a position that does not interfere with the two side walls and the at least one partition wall, allowing the bottom port liquid cooling plate to move along the transverse direction of the shell, when the bottom port liquid cooling plate is in the final installation position the limiting protrusion is in a position that interferes with the two side walls and the at least one partition wall to prevent the bottom port liquid cooling plate from being moved along the transverse direction.

6. The connector shell assembly of claim 1, wherein the bottom port liquid cooling plate is a single rectangular plate with a predetermined thickness, the bottom port liquid cooling plate has two opposite ends in a length direction of the bottom port liquid cooling plate and two opposite sides in a width direction of the bottom port liquid cooling plate, a liquid cooling channel formed in the bottom port liquid cooling plate allows a cooling liquid to flow therethrough, and two openings formed on an end face of one end of the bottom port liquid cooling plate, the two openings communicate with the liquid cooling channel, the two openings are respectively close to both sides of the bottom port liquid cooling plate, one of the two openings is a cooling liquid inlet and the other of the two openings is a cooling liquid outlet.

7. The connector shell assembly of claim 1, wherein the bottom port liquid cooling plate includes:
a pair of strip-shaped bodies that are opposite in a width direction of the bottom port liquid cooling plate, the pair of strip-shaped bodies extend along a length direction of the bottom port liquid cooling plate;
a pair of thin plate parts between the pair of strip-shaped bodies, each thin plate part is connected to one strip-shaped body; and
an end body extending along the width direction, the end body is connected to one end of each of the pair of strip-shaped bodies and the pair of thin plate parts, a thickness of the pair of strip-shaped bodies and the end body is greater than a thickness of the pair of thin plate parts, the pair of thin plate parts are spaced and opposite each other in the width direction, the pair of thin plate parts thermally contact the top of the bottom port heat sink.

8. The connector shell assembly of claim 7, wherein a liquid cooling channel is formed in the pair of strip-shaped bodies and the end body allowing a cooling liquid to flow therethrough, two openings are respectively formed on end faces of the other ends of the pair of strip-shaped bodies, the two openings communicate with the liquid cooling channel, one of the two openings is a cooling liquid inlet, and the other of the two openings is a cooling liquid outlet.

9. The connector shell assembly of claim 1, wherein the bottom port liquid cooling plate includes:
a thick plate part extending along a length direction of the bottom port liquid cooling plate at one side in a width direction of the bottom port liquid cooling plate; and
a thin plate part extending along the length direction at the other side in the width direction, a thickness of the thick plate part is greater than a thickness of the thin plate part, one side of the thin plate part is connected to one side of the thick plate part, the thin plate part thermally contacts the top of the bottom port heat sink.

10. The connector shell assembly of claim 9, wherein a liquid cooling channel formed in the thick plate part allows a cooling liquid to flow therethrough, two openings are formed on an end face of one end of the thick plate part, the two openings communicate with the liquid cooling channel, one of the two openings is a cooling liquid inlet, and the other of the two openings is a cooling liquid outlet.

11. The connector shell assembly of claim 6, further comprising two connection pipes each connected to one of the two openings on the bottom port liquid cooling plate, the two connection pipes connect the bottom port liquid cooling plate to a cooling circuit, one of the two connection pipes is an inlet pipe, and the other of the two connection pipes is an outlet pipe.

12. The connector shell assembly of claim 11, further comprising two pipe joints each connected to one of the two openings on the bottom port liquid cooling plate, the two connection pipes are each connected to the one of the two openings through one of the two pipe joints.

13. The connector shell assembly according to claim 1, further comprising a top port heat sink installed on a top wall of the row of top ports, a bottom of the top port heat sink protrudes into the row of top ports and thermally contacts a mating connector inserted into each top port, a top port liquid cooling plate installed on the top of the shell and the top port heat sink thermally contacts the top of the top port heat sink, a liquid cooling channel formed in the top port liquid cooling plate allows a cooling liquid to flow therethrough, the liquid cooling channel has an inlet port and an outlet port each respectively connecting to an inlet pipe and an outlet pipe.

14. A connector shell assembly, comprising:
a shell having a row of bottom ports and a row of top ports adjacent to each other in a height direction of the shell;
a plurality of bottom port heat sinks each installed on a bottom wall of each bottom port, a top of each bottom port heat sink protrudes into one bottom port and thermally contacts a mating connector inserted into the one bottom port;
a circuit board formed with cutouts allowing the bottom of each bottom port heat sink to pass through, the shell is fixed to a top surface of the circuit board; and
a bottom port liquid cooling plate fixed to a bottom surface of the circuit board and in thermal contact with the bottom of the bottom port heat sink, a liquid cooling channel formed in the bottom port liquid cooling plate allows a cooling liquid to flow therethrough, the liquid cooling channel has an inlet port and an outlet port respectively connecting with an inlet pipe and an outlet pipe.

15. The connector shell assembly of claim 14, wherein threaded connection members detachably fasten the bottom port liquid cooling plate to the bottom surface of the circuit board.

16. The connector shell assembly of claim 14, further comprising a top port heat sink installed on a top wall of the row of top ports, a bottom of the top port heat sink protrudes into the row of top ports and thermally contacts a mating connector inserted into each top port, and a top port liquid cooling plate installed on the top of the shell, the top port heat sink thermally contacts the top of the top port heat sink, a liquid cooling channel formed in the top port liquid cooling plate allows a cooling liquid to flow therethrough, the liquid cooling channel has an inlet port and an outlet port respectively connecting with an inlet pipe and an outlet pipes.

17. A connector shell assembly, comprising:
a shell having a row of bottom ports and a row of top ports adjacent to each other in a height direction of the shell, and a transverse slot between a top wall of the row of bottom ports and a bottom wall of the row of top ports;
a plurality of bottom port heat sinks each installed on the top wall of each bottom port, a bottom of each bottom port heat sink protrudes into one bottom port and thermally contacts a mating connector inserted into the one bottom port;
a top port heat sink installed on the bottom wall of the row of top ports, a bottom of the top port heat sink protrudes into the row of top ports and thermally contacts a mating connector inserted into each top port; and
a bottom port liquid cooling plate inserted into the transverse slot of the shell thermally contacts each bottom port heat sink and the top port heat sink and cools the bottom port heat sink and the top port heat sink through a cooling liquid flowing through the bottom port liquid cooling plate.

18. The connector shell assembly of claim 17, wherein the shell has two side walls opposite each other in a transverse direction of the shell, the transverse slot has an inlet located on one side wall of the shell and an outlet located on the other side wall of the shell, the bottom port liquid cooling plate is inserted from the inlet of the transverse slot, one end of the bottom port liquid cooling plate extends from the outlet of the transverse slot, an elastic locking piece is formed on the other side wall of the shell, and a locking step is formed on one end of the bottom port liquid cooling plate, the elastic locking piece rests against the locking step and locks the bottom port liquid cooling plate in the transverse slot.

19. The connector shell assembly of claim 17, wherein a liquid cooling channel formed in the bottom port liquid cooling plate allows a cooling liquid to flow therethrough, and two openings connected to the liquid cooling channel are formed on an end face of the other end of the bottom port liquid cooling plate.

20. The connector shell assembly of claim 19, further comprising two pipe joints each connected to one of the two openings of the liquid cooling channel, and two connection pipes each connected to one of the two pipe joints, one of the two connection pipes is an inlet pipe, and the other of the two connection pipes is an outlet pipe.

21. A connector, comprising:
a connector shell assembly including a shell, a plurality of bottom port heat sinks, and a bottom port liquid cooling plate, the shell has a row of bottom ports and a row of top ports adjacent to each other in a height direction of the shell, and a transverse slot between a top wall of the row of bottom ports and a bottom wall of the row of top ports, each bottom port heat sink is installed on the top wall of each bottom port, a bottom of each bottom port heat sink protrudes into one bottom port and thermally contacts a mating connector inserted into the one bottom port, and the bottom port liquid cooling plate inserted into the transverse slot of the shell thermally contacts a top of the bottom port heat sink and cools the bottom port heat sink with a cooling liquid flowing through the bottom port liquid cooling plate; and
a plurality of terminal modules each installed in the shell respectively correspond to the row of bottom ports and the row of top ports, each terminal module has an insulator and terminals arranged in the insulator, each terminal mates with mating terminals of an inserted mating connector.

22. The connector of claim 21, further comprising a circuit board, a bottom of the shell is fixed to the circuit board, and each terminal is electrically connected to the circuit board.

23. The connector of claim 22, wherein a pin is formed at the bottom of the shell, and a hole is formed in the circuit board, the pin is press fit into the hole and fixes the shell to the circuit board.
